(19) United States
(12) Patent Application Publication
(10) Pub. No.: US 2013/0106436 A1
(43) Pub. Date: May 2, 2013

(54) Touch Sensor With Measurement to Noise Synchronization

(71) Applicants: Samuel Brunet, Cowes (GB); Richard Paul Collins, Southampton (GB)

(72) Inventors: Samuel Brunet, Cowes (GB); Richard Paul Collins, Southampton (GB)

(21) Appl. No.: 13/285,739

(22) Filed: Oct. 31, 2011

(51) Int. Cl. G01R 29/26

(52) U.S. Cl. 324/613

(57) ABSTRACT

In one embodiment, a method includes sensing by a touch sensor a periodic noise signal caused by an external power source removably coupled to the touch sensor. A measurement signal that is synchronized to the periodic noise signal may be generated and transmitted to a location of the touch sensor. The method may further include detecting whether a touch has occurred at or near the location of the touch sensor based on a response of the location of the touch sensor to the measurement signal.

### TECHNICAL FIELD

This disclosure generally relates to touch sensors.

### BACKGROUND

A touch position sensor may detect the presence and location of a touch or the proximity of an object (such as a user's finger or a stylus) within a touch-sensitive area of the touch sensor overlaid on a display screen, for example. In a touch sensitive display application, the touch position sensor may enable a user to interact directly with what is displayed on the screen, rather than indirectly with a mouse or touch pad. A touch sensor may be attached to or provided as part of a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

There are a number of different types of touch position sensors, such as (for example) resistive touch screens, surface acoustic wave touch screens, and capacitive touch screens. Herein, reference to a touch sensor may encompass a touch screen, and vice versa, where appropriate. When an object touches or comes within proximity of the surface of the capacitive touch screen, a change in capacitance may occur within the touch screen at the location of the touch or proximity. A controller may process the change in capacitance to determine its position on the touch screen.

### BRIEF DESCRIPTION OF THE DRAWINGS

FIG. 1 illustrates an example device coupled to an external power source that may introduce a noise signal into a touch sensor of the example device.

FIG. 2 illustrates a waveform of an example noise signal and waveforms of an example synchronization signal and example measurement signal that are each synchronized to the example noise signal.

FIG. 3 illustrates an example controller operable to generate a measurement signal that is synchronized to a noise signal sensed by an example noise sensor.

FIG. 4 illustrates an example method for generating a measurement signal that is synchronized to a noise signal.

FIG. 5 illustrates an example method for generating a synchronization signal that is synchronized to a noise signal.

### DESCRIPTION OF EXAMPLE EMBODIMENTS

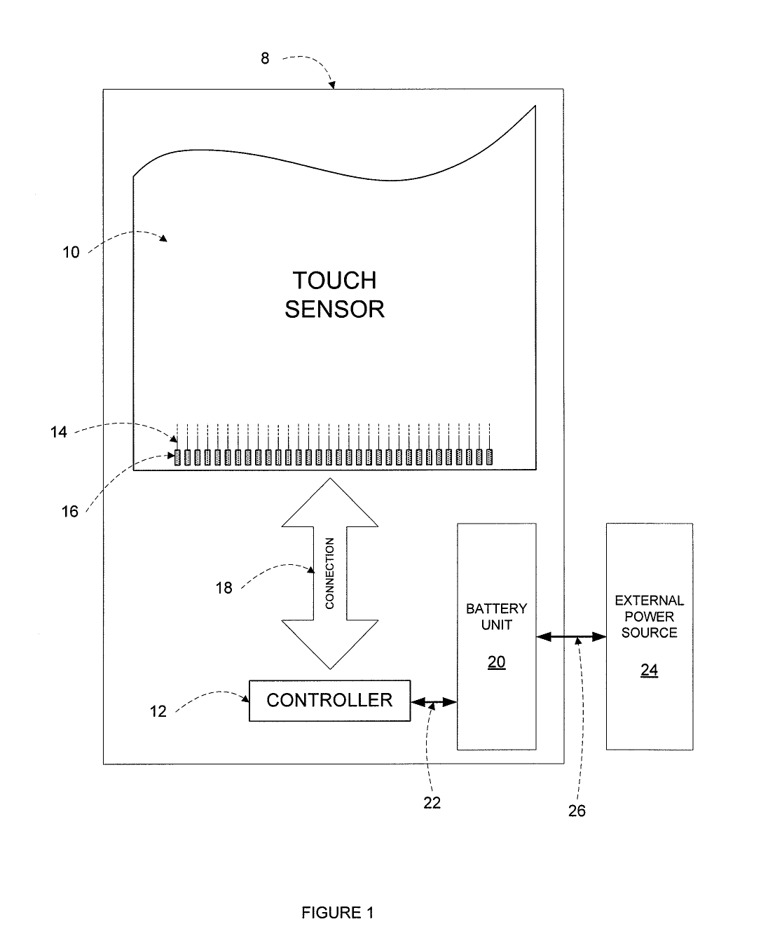

FIG. 1 illustrates an example touch sensor 10 with an example controller 12. Herein, reference to a touch sensor may encompass a touch screen, and vice versa, where appropriate. Touch sensor 10 and controller 12 may detect the presence and location of a touch or the proximity of an object within a touch-sensitive area of touch sensor 10. Herein, reference to a touch sensor may encompass both the touch sensor and its controller, where appropriate. Similarly, reference to a controller may encompass both the controller and its touch sensor, where appropriate. Touch sensor 10 may include one or more touch-sensitive areas, where appropriate. Touch sensor 10 may include an array of drive and sense electrodes (or an array of electrodes of a single type) disposed on one or more substrates, which may be made of a dielectric material. Herein, reference to a touch sensor may encompass both the electrodes of the touch sensor and the substrate(s) that they are disposed on, where appropriate. Alternatively, where appropriate, reference to a touch sensor may encompass the electrodes of the touch sensor, but not the substrate(s) that they are disposed on.

An electrode (whether a drive electrode or a sense electrode) may be an area of conductive material forming a shape, such as for example a disc, square, rectangle, other suitable shape, or suitable combination of these. One or more cuts in one or more layers of conductive material may (at least in part) create the shape of an electrode, and the area of the shape may (at least in part) be bounded by those cuts. In particular embodiments, the conductive material of an electrode may occupy approximately 100% of the area of its shape. As an example and not by way of limitation, an electrode may be made of indium tin oxide (ITO) and the ITO of the electrode may occupy approximately 100% of the area of its shape, where appropriate. In particular embodiments, the conductive material of an electrode may occupy approximately 5% of the area of its shape. As an example and not by way of limitation, an electrode may be made of fine lines of metal or other conductive material (such as for example copper, silver, or a copper- or silver-based material) and the fine lines of conductive material may occupy approximately 5% of the area of its shape in a hatched, mesh, or other suitable pattern. Although this disclosure describes or illustrates particular electrodes made of particular conductive material forming particular shapes with particular fills having particular patterns, this disclosure contemplates any suitable electrodes made of any suitable conductive material forming any suitable shapes with any suitable fills having any suitable patterns. Where appropriate, the shapes of the electrodes (or other elements) of a touch sensor may constitute in whole or in part one or more macro-features of the touch sensor. One or more characteristics of the implementation of those shapes (such as, for example, the conductive materials, fills, or patterns within the shapes) may constitute in whole or in part one or more micro-features of the touch sensor. One or more macro-features of a touch sensor may determine one or more characteristics of its functionality, and one or more micro-features of the touch sensor may determine one or more optical features of the touch sensor, such as transmittance, refraction, or reflection.

One or more portions of the substrate of touch sensor 10 may be made of polyethylene terephthalate (PET) or another suitable material. This disclosure contemplates any suitable substrate with any suitable portions made of any suitable material. In particular embodiments, the drive or sense electrodes in touch sensor 10 may be made of ITO in whole or in part. In particular embodiments, the drive or sense electrodes in touch sensor 10 may be made of fine lines of metal or other conductive material. As an example and not by way of limitation, one or more portions of the conductive material may be copper or copper-based and have a thickness of approximately 5 μm or less and a width of approximately 10 μm or less. As another example, one or more portions of the conductive material may be silver or silver-based and similarly have a thickness of approximately 5 μm or less and a width of approximately 10 μm or less. This disclosure contemplates any suitable electrodes made of any suitable material.

A mechanical stack may contain the substrate (or multiple substrates) and the conductive material forming the drive or sense electrodes of touch sensor 10. As an example and not by way of limitation, the mechanical stack may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with the conductive material forming the drive or sense electrodes. The mechanical stack may also include a second layer of OCA and a dielectric layer (which may be made of PET or another suitable material, similar to the substrate with the conductive material forming the drive or sense electrodes). As an alternative, where appropriate, a thin coating of a dielectric material may be applied instead of the second layer of OCA and the dielectric layer. The second layer of OCA may be disposed between the substrate with the conductive material making up the drive or sense electrodes and the dielectric layer, and the dielectric layer may be disposed between the second layer of OCA and an air gap to a display of a device including touch sensor 10 and controller 12. As an example only and not by way of limitation, the cover panel may have a thickness of approximately 1 mm; the first layer of OCA may have a thickness of approximately 0.05 mm; the substrate with the conductive material forming the drive or sense electrodes may have a thickness of approximately 0.05 mm; the second layer of OCA may have a thickness of approximately 0.05 mm; and the dielectric layer may have a thickness of approximately 0.05 mm. Although this disclosure describes a particular mechanical stack with a particular number of particular layers made of particular materials and having particular thicknesses, this disclosure contemplates any suitable mechanical stack with any suitable number of any suitable layers made of any suitable materials and having any suitable thicknesses. As an example and not by way of limitation, in particular embodiments, a layer of adhesive or dielectric may replace the dielectric layer, second layer of OCA, and air gap described above, with there being no air gap to the display.

Touch sensor 10 may implement a capacitive form of touch sensing. In a mutual-capacitance implementation, touch sensor 10 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other across a space between them. A pulsed or alternating voltage applied to the drive electrode (by controller 12) may induce a charge on the sense electrode, and the amount of charge induced may be susceptible to external influence (such as a touch or the proximity of an object). When an object touches or comes within proximity of the capacitive node, a change in capacitance may occur at the capacitive node and controller 12 may measure the change in capacitance. By measuring changes in capacitance throughout the array, controller 12 may determine the position of the touch or proximity within the touch-sensitive area(s) of touch sensor 10.

In a self-capacitance implementation, touch sensor 10 may include an array of electrodes of a single type that may each form a capacitive node. When an object touches or comes within proximity of the capacitive node, a change in self-capacitance may occur at the capacitive node and controller 12 may measure the change in capacitance, for example, as a change in the amount of charge needed to raise the voltage at the capacitive node by a pre-determined amount. As with a mutual-capacitance implementation, by measuring changes in capacitance throughout the array, controller 12 may determine the position of the touch or proximity within the touch-sensitive area(s) of touch sensor 10. This disclosure contemplates any suitable form of capacitive touch sensing, where appropriate.

In particular embodiments, one or more drive electrodes may together form a drive line running horizontally or vertically or in any suitable orientation. Similarly, one or more sense electrodes may together form a sense line running horizontally or vertically or in any suitable orientation. In particular embodiments, drive lines may run substantially perpendicular to sense lines. Herein, reference to a drive line may encompass one or more drive electrodes making up the drive line, and vice versa, where appropriate. Similarly, reference to a sense line may encompass one or more sense electrodes making up the sense line, and vice versa, where appropriate.

Touch sensor 10 may have drive and sense electrodes disposed in a pattern on one side of a single substrate. In such a configuration, a pair of drive and sense electrodes capacitively coupled to each other across a space between them may form a capacitive node. For a self-capacitance implementation, electrodes of only a single type may be disposed in a pattern on a single substrate. In addition or as an alternative to having drive and sense electrodes disposed in a pattern on one side of a single substrate, touch sensor 10 may have drive electrodes disposed in a pattern on one side of a substrate and sense electrodes disposed in a pattern on another side of the substrate. Moreover, touch sensor 10 may have drive electrodes disposed in a pattern on one side of one substrate and sense electrodes disposed in a pattern on one side of another substrate. In such configurations, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across a dielectric at the intersection. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

As described above, a change in capacitance at a capacitive node of touch sensor 10 may indicate a touch or proximity input at the position of the capacitive node. Controller 12 may detect and process the change in capacitance to determine the presence and location of the touch or proximity input. Controller 12 may then communicate information about the touch or proximity input to one or more other components (such one or more central processing units (CPUs) or digital signal processors (DSPs)) of a device that includes touch sensor 10 and controller 12, which may respond to the touch or proximity input by initiating a function of the device (or an application running on the device) associated with it. Although this disclosure describes a particular controller having particular functionality with respect to a particular device and a particular touch sensor, this disclosure contemplates any suitable controller having any suitable functionality with respect to any suitable device and any suitable touch sensor.

Controller 12 may be one or more integrated circuits (ICs)—such as for example general-purpose microprocessors, microcontrollers, programmable logic devices or arrays, application-specific ICs (ASICs) on a flexible printed circuit (FPC) bonded to the substrate of touch sensor 10, as described below. Controller 12 may include a processor unit, a drive unit, a sense unit, and a storage unit. The drive unit may supply drive signals to the drive electrodes of touch sensor 10. The sense unit may sense charge at the capacitive nodes of touch sensor 10 and provide measurement signals to the processor unit representing capacitances at the capacitive nodes. The processor unit may control the supply of drive signals to the drive electrodes by the drive unit and process measurement signals from the sense unit to detect and process the presence and location of a touch or proximity input within the touch-sensitive area(s) of touch sensor 10. The processor unit may also track changes in the position of a touch or proximity input within the touch-sensitive area(s) of touch sensor 10. The storage unit may store programming for execution by the processor unit, including programming for controlling the drive unit to supply drive signals to the drive electrodes, programming for processing measurement signals from the sense unit, and other suitable programming, where appropriate. Although this disclosure describes a particular controller having a particular implementation with particular components, this disclosure contemplates any suitable controller having any suitable implementation with any suitable components.

Tracks 14 of conductive material disposed on the substrate of touch sensor 10 may couple the drive or sense electrodes of touch sensor 10 to bond pads 16, also disposed on the substrate of touch sensor 10. As described below, bond pads 16 facilitate coupling of tracks 14 to controller 12. Tracks 14 may extend into or around (e.g. at the edges of) the touch-sensitive area(s) of touch sensor 10. Particular tracks 14 may provide drive connections for coupling controller 12 to drive electrodes of touch sensor 10, through which the drive unit of controller 12 may supply drive signals to the drive electrodes. Other tracks 14 may provide sense connections for coupling controller 12 to sense electrodes of touch sensor 10, through which the sense unit of controller 12 may sense charge at the capacitive nodes of touch sensor 10. Tracks 14 may be made of fine lines of metal or other conductive material. As an example and not by way of limitation, the conductive material of tracks 14 may be copper or copper-based and have a width of approximately 100 μm or less. As another example, the conductive material of tracks 14 may be silver or silver-based and have a width of approximately 100 μm or less. In particular embodiments, tracks 14 may be made of ITO in whole or in part in addition or as an alternative to fine lines of metal or other conductive material. Although this disclosure describes particular tracks made of particular materials with particular widths, this disclosure contemplates any suitable tracks made of any suitable materials with any suitable widths. In addition to tracks 14, touch sensor 10 may include one or more ground lines terminating at a ground connector (which may be a bond pad 16) at an edge of the substrate of touch sensor 10 (similar to tracks 14).

Bond pads 16 may be located along one or more edges of the substrate, outside the touch-sensitive area(s) of touch sensor 10. As described above, controller 12 may be on an FPC. Bond pads 16 may be made of the same material as tracks 14 and may be bonded to the FPC using an anisotropic conductive film (ACF). Connection 18 may include conductive lines on the FPC coupling controller 12 to bond pads 16, in turn coupling controller 12 to tracks 14 and to the drive or sense electrodes of touch sensor 10. This disclosure contemplates any suitable connection 18 between controller 12 and touch sensor 10.

Device 8 may also include a battery unit 20. Battery unit 20 may include one or more rechargeable batteries that supply electrical power to various components of device 8, such as controller 12, a display, or other device electronics. Battery unit 20 may also include any suitable circuitry for recharging the batteries through electrical power received from external power source 24. In particular embodiments, battery unit 20 may be operable to transfer electrical power from external power source 24 to one or more components of device 8 such that the component(s) may function without drawing electrical power from the one or more batteries of battery unit 20. In particular embodiments, battery unit 20 or external power source 24 may be operable to supply electrical power to controller 12 via power connector 22.

In particular embodiments, battery unit 20 may be removably coupled to external power source 24 via charger connection 26. External power source 24 may be operable to recharge one or more batteries of battery unit 20 when charge stored by the one or more batteries of battery unit 20 is partially or completely depleted. In particular embodiments, external power source 24 may be operable to supply power to one or more components of device 8, such as controller 12, a display, or other device electronics.

External power source 24 may provide electrical power with any suitable characteristics. In particular embodiments, external power source 24 may supply alternating current (AC) electrical power with any suitable voltage or frequency. As an example and not by way of limitation, external power source 24 may supply an AC voltage between 100 and 240 volts (V) at a frequency of substantially 50 Hz or 60 Hz. In particular embodiments, external power source 24 may supply direct current (DC) electrical power with any suitable voltage. As an example and not by way of limitation, external power source 24 may supply a DC voltage of substantially 5V or 12V. In particular embodiments, external power source 24 may be a universal serial bus (USB) port of a computer or a cigarette lighter receptacle of an automobile. Although this disclosure describes particular external power sources, this disclosure contemplates any suitable external power sources.

In particular embodiments, charger connection 26 or battery unit 20 may be configured to convert electrical power received from external power source 24 to a form that is suitable for recharging the one or more batteries of battery unit 20 or for operating one or more other components of device 8. As an example and not by way of limitation, charger connection 26 or battery unit 20 may include a voltage inverter configured to convert an AC voltage into a DC voltage. As another example, charger connection 26 or battery unit 20 may be operable to modify the voltage level or current level of the electrical power received from external power source 24 to a level that is suitable for recharging the one or more batteries of battery unit 20 or for operating one or more components of device 8.

In particular embodiments, external power source 24 may introduce a noise signal into touch sensor 10 of device 8. As an example and not by way of limitation, external power source 24 may produce a common mode noise signal that is coupled to a sense line of touch sensor 10 when a sense electrode coupled to the sense line is touched. The noise signal introduced to touch sensor 10 by external power source 24 may negatively affect measurements performed by touch sensor 10 and controller 12. As an example and not by way of limitation, the noise signal may be superimposed on a signal that is analyzed by controller 12 to detect whether a touch has occurred at a particular location of touch sensor 10. The noise signal may result in erroneous measurements by controller 12 (such as undetected touches) or decreased response time due to additional measurements required to filter out the noise signal. In particular embodiments, the noise signal may have relatively large voltage swings and fast edges and thus may be difficult to filter from a signal that includes information indicative of whether a touch has occurred at a location of the touch sensor.

In particular embodiments, the effects of the noise signal may be mitigated by synchronizing measurements performed by touch sensor 10 and controller 12 to the noise signal. In particular embodiments, the noise signal caused by external power source 24 may be periodic, that is, the noise signal may include a general pattern that repeats at a substantially constant interval. The touch sensor measurements may be configured to coincide with a particular portion of this general pattern. As an example and not by way of limitation, the touch sensor measurements may occur while the noise signal is relatively stable or mildly oscillating. In such embodiments, the effects of the noise signal on the touch sensor measurements may be reduced relative to the effects of the noise signal on touch sensor measurements performed at different portions of the general pattern of the noise signal. In particular embodiments, the accuracy of touch sensor measurements that are synchronized to the noise signal caused by external power source 24 may be substantially similar to the accuracy of measurements performed when the noise signal is not present at the touch sensor 10.

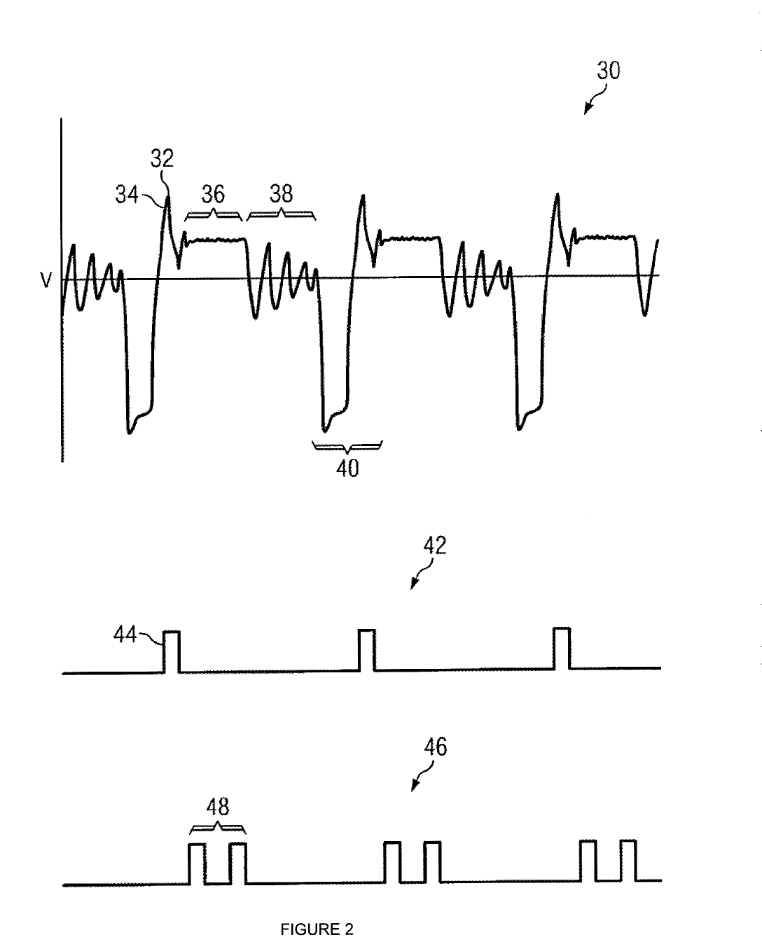

FIG. 2 illustrates a waveform of an example noise signal 30 and waveforms of an example synchronization signal 42 and example measurement signal 46 that are each synchronized to the example noise signal 30. The waveform of noise signal 30 is an example representation of a noise signal that may be introduced into touch sensor 8 from external power source 24. In particular embodiments, noise signal 30 may be periodic, that is, it may include a general pattern (i.e. cycle) that repeats at a substantially constant interval. The general pattern of noise signal 30 may repeat at any suitable frequency. In particular embodiments, the frequency of the noise signal may be substantially equivalent to or related to the frequency of electrical power supplied by the external power source 24.

The waveform of noise signal 30 may have any suitable shape. In general, the waveform shape of noise signal 30 may be dependent on the external power source 24 and the load on the external power source. In the embodiment depicted in FIG. 2, each cycle of noise signal 30 includes a peak voltage 32 wherein the voltage of the noise signal 30 is at a maximum, a stable portion 36 wherein the voltage of noise signal 30 is generally constant, a ringing portion 38 wherein the voltage level oscillates up and down, and a spiking portion 40 that includes large voltage swings with fast edges. Although this disclosure describes a particular waveform of a noise signal, this disclosure contemplates any suitable noise signal waveform.

In particular embodiments, a touch sensor measurement that is performed at a time that is aligned with one or more portions of noise signal 30 may be less susceptible to corruption by noise signal 30 than a similar touch sensor measurement aligned with a different portion of noise signal 30. As an example and not by way of limitation, a touch sensor measurement performed during stable portion 36 or ringing portion 38 of noise signal 30 may be less susceptible to noise signal effects than a touch sensor measurement performed during spiking portion 40. Thus, touch sensor measurements that are synchronized to noise signal 30 (e.g. performed during a particular portion of a repeating pattern of noise signal 30) may improve touch sensor measurement performance.

In particular embodiments, a component of device 8 (e.g. controller 12) may generate a synchronization signal 42 that facilitates alignment of touch sensor measurements with a particular portion of a repeating pattern of noise signal 30. Synchronization signal 42 may include synchronization events 44. A synchronization event 44 may include any suitable signaling, such as one or more electrical pulses, a toggling of the synchronization signal 42 from high to low or low to high, or other suitable signaling. As an example and not by way of limitation, each synchronization event 44 is shown as a single electrical pulse in FIG. 2. Although this disclosure describes a particular waveform of synchronization signal 42, this disclosure contemplates any suitable waveform of synchronization signal 42 having any suitable shape or other characteristics.

In particular embodiments, the synchronization signal 42 may be generated based on noise signal 30. As an example and not by way of limitation, synchronization signal 42 may be synchronized to the noise signal 30 (e.g. each synchronization event 44 may be generated to coincide with a particular portion of a repeating pattern of noise signal 30) As an example and not by way of limitation, synchronization events 44 are shown as substantially aligned with peak voltages 32 of noise signal 30. In particular embodiments, the synchronization events 44 may occur at a frequency that is the same frequency as the noise signal 30. In other particular embodiments, the synchronization events 44 may occur at a frequency that is based on a frequency of the noise signal 30. As an example and not by way of limitation, synchronization events 44 may occur at a fraction of the frequency of the noise signal 30, such as ¼, ½, or other fraction.

In particular embodiments, the generation of a synchronization event 44 may be triggered by a condition of the noise signal 30. Synchronization event 44 may be triggered by any suitable condition of noise signal 30, such as a crossing of an upper or lower threshold level, a ringing sequence, a stable sequence, a spike, or other suitable condition. In particular embodiments, the beginning or end of a synchronization event 44 may be triggered by a condition of noise signal 30. In particular embodiments, as shown in FIG. 2, the beginning of synchronization event 44 (e.g. an electrical pulse) may be triggered by noise signal 30 rising above a threshold 34 and the end of synchronization event 44 may be triggered by noise signal 30 falling below threshold 34.

In particular embodiments, a synchronization event 44 may be generated at any suitable time with respect to a condition that triggers the synchronization event. As examples and not by way of limitation, a synchronization event may be generated at substantially the same time as or immediately after a condition of the noise signal 30 occurs. As another example, the synchronization event 44 may occur a predetermined period of time after the condition of the noise signal 30 occurs.

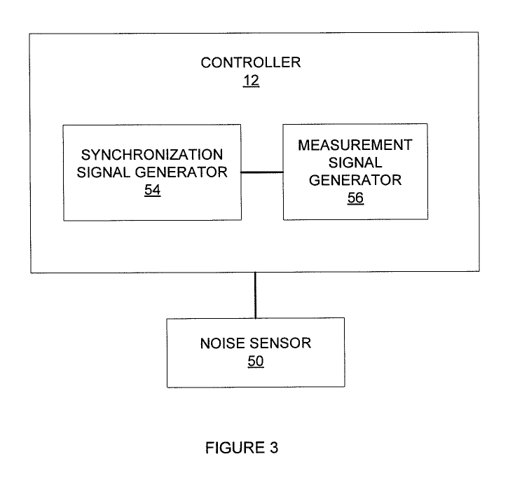

Synchronization signal 42 may be generated in any suitable manner. In a particular embodiment, a comparator with a programmable threshold (described in further detail in connection with FIG. 3) generates the synchronization signal 42. The comparator may generate an active signal (which may be high or low depending on the particular implementation) during a time period when the voltage level of noise signal 30 is above the threshold of the comparator (e.g. threshold 34 of FIG. 2). In particular embodiments, a comparator with a programmable threshold may be operable to generate a synchronization signal 42 similar to the synchronization signal shown in FIG. 2.

In particular embodiments, a component of device 8 (e.g. controller 12) may generate a measurement signal 46 that is synchronized with noise signal 30. In particular embodiments, measurement signal 46 may include measurement events 48. A measurement event 48 may include any suitable signaling that facilitates a determination of whether a touch or proximity input has occurred at one or more locations of touch sensor 10. As an example and not by way of limitation, a measurement event 48 may include the generation of one or more drive signals (e.g. electrical pulses) that may be transmitted to an electrode (e.g. a drive electrode) of touch sensor 10. In the embodiment depicted in FIG. 2, each measurement event 48 of the measurement signal 46 is shown as a series of two electrical pulses. Although this disclosure describes a particular waveform of a measurement signal 46, this disclosure contemplates any suitable waveform of measurement signal 46 having any suitable shape or other characteristics.

As described above, measurement signal 46 may be synchronized with noise signal 30. As an example and not by way of limitation, each synchronization event 44 may be generated to coincide with a particular portion of a repeating pattern of noise signal 30. In particular embodiments, measurement signal 46 may also be synchronized with synchronization signal 42. As an example and not by way of limitation, the amount of time between a synchronization event 44 and a corresponding measurement event 48 may be substantially constant in each cycle of measurement signal 46.

In particular embodiments, measurement events 48 may occur at a frequency that is the same frequency as the noise signal 30 or the synchronization signal 42. In other particular embodiments, measurement events 48 may occur at a frequency that is based on a frequency of noise signal 30 or a frequency of synchronization signal 42. As an example and not by way of limitation, measurement events 48 may occur at a fraction of the frequency of noise signal 30 or synchronization signal 42, such as ¼, ½, or other fraction.

In particular embodiments, a measurement event 48 may be generated in response to a synchronization event 44. A measurement event 48 may be generated to occur at any suitable time with respect to a synchronization event. In particular embodiments, a measurement event 48 may occur at substantially the same time or immediately after a corresponding synchronization event 44. In other embodiments, a measurement event 44 may occur a particular amount of time after a corresponding synchronization event 44 occurs. As an example and not by way of limitation, in FIG. 2, each measurement event 48 is shown as occurring a particular time period after a corresponding synchronization event 44 begins. In particular embodiments, the particular time period may be adjusted such that each measurement event 48 may coincide with a particular portion of noise signal 30. In the embodiment depicted in FIG. 2, each measurement event 48 coincides with a stable portion 36 of noise signal 30. In other embodiments, measurement events 48 may be configured to coincide with any suitable portion of a repeating pattern of noise signal 30.

FIG. 3 illustrates an example controller 12 operable to generate a measurement signal 46 that is synchronized to a noise signal 30 sensed by an example noise sensor 50. Controller 12 may include synchronization signal generator 54 and measurement signal generator 56. In particular embodiments, controller 12 may also include one or more other components as described above in connection with FIG. 1. In particular embodiments, synchronization signal generator 54 or measurement signal generator 56 may include or provide the functionality of one or more of the other components of controller 12 described above. As an example and not by way of limitation, measurement signal generator 56 may include one or more drive units operable to provide drive signals to one or more drive electrodes of touch sensor 10.

In a particular embodiment, controller 12 may be coupled to noise sensor 50. Noise sensor 50 may include any suitable circuitry configured to sense noise signal 30. In particular embodiments, noise sensor 50 may be operable provide noise signal 30 to controller 12 for analysis by the controller. In particular embodiments, sensor 50 may provide noise signal 30 in isolation. In other embodiments, noise sensor 50 may provide noise signal 30 in addition to (e.g. superimposed on) one or more other signals (e.g. a signal from a sense line coupled to an electrode). In a particular embodiment, noise sensor 50 may include or be coupled to one or more electrodes or sense lines of touch sensor 10.

Synchronization signal generator 54 may include any suitable circuitry configured to analyze noise signal 30 and generate a synchronization signal 42. In particular embodiments, synchronization signal generator 54 may be configured to generate synchronization signal 42 based on one or more conditions of noise signal 30. For example, in particular embodiments, synchronization signal generator 54 may generate synchronization events 44 of synchronization signal 42 in response to a detection of a threshold crossing, ringing sequence, stable sequence, spiking sequence, or other suitable condition of noise signal 30. In particular embodiments, synchronization signal generator 54 may generate a periodic synchronization signal 42 that has a frequency based on the frequency of noise signal 30.

In a particular embodiment, synchronization signal generator 54 includes a comparator coupled to noise sensor 50. The synchronization signal generator 54 may also include a programmable voltage source coupled to the comparator and operable to provide an adjustable voltage to the comparator. In operation, the comparator may be configured to generate an active signal (which may be high or low depending on the particular implementation) when the voltage level of noise signal 30 is above the voltage level provided by the programmable voltage source and an inactive signal at other times. In particular embodiments, the programmable voltage source may be configured to provide a voltage level that is slightly lower than the peak voltage 32 of noise signal 30. In such a configuration, the comparator may be operable to generate a synchronization signal 42 with periodic electrical pulses such as those shown in FIG. 2.

The voltage level provided by the programmable voltage source may be adjusted in any suitable manner. As an example and not by way of limitation, the programmable voltage source may include a plurality of switches that may each be selectively opened or closed to adjust the voltage level. In particular, the voltage level of the programmable voltage source may be adjusted according to an adjustment algorithm. The adjustment algorithm may alter the voltage level of the programmable voltage source until a suitable level is reached. In particular embodiments, the voltage level of the programmable voltage source may be adjusted based on an analysis of the noise signal 30, synchronization signal 42, measurement signal 46, touch sensor measurement characteristics (e.g. an accuracy or signal-to-noise ratio of the measurements), other suitable signal or condition, or combination thereof.

Measurement signal generator 56 may include any suitable circuitry for generating measurement signal 42. In particular embodiments, measurement signal generator 56 may include a drive unit that generates measurement signal 46. In particular embodiments, measurement signal 46 may include one or more measurement events 48 comprising drive signals, such as electrical pulses, supplied to the drive electrodes of touch sensor 10. In particular embodiments, measurement signal generator 56 may be operable to generate measurement signal 46 based on synchronization events 44 of the synchronization signal 42. In particular embodiments, measurement signal generator 56 may include a programmable delay circuit that is operable to adjust the timing of each event of a series of periodic measurement events 48 with respect to each synchronization event 44 of a periodic sequence of synchronization events 44. In particular embodiments, the timing of the measurement events 48 of a measurement signal 46 may be adjusted until an optimum or predetermined signal to noise ratio of a touch sensor measurement is achieved. In particular embodiments, the programmable delay circuit may be adjusted based on an analysis of the noise signal 30, synchronization signal 42, measurement signal 46, touch sensor measurements (e.g. an accuracy or signal-to-noise ratio of the measurements), other suitable signal or condition, or combination thereof.

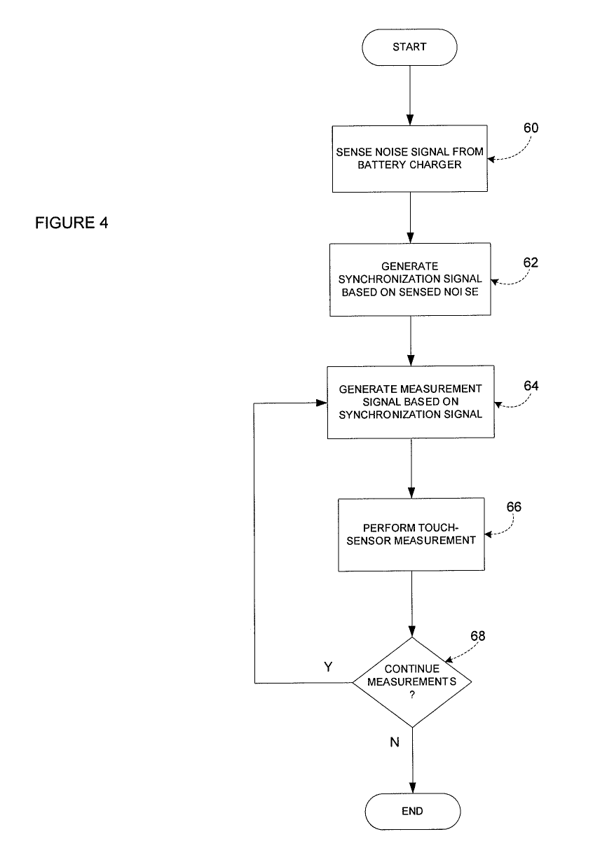

FIG. 4 illustrates an example method for generating a measurement signal 46 that is synchronized to a noise signal 30. The method may begin at step 60, where a noise signal 30 caused by external power source 24 is sensed at one or more locations of device 8. In particular embodiments, noise signal 30 may be sensed by touch sensor 10. Noise signal 30 may be a common mode signal generated by external power source 24 that is coupled to touch sensor 10 when a location of touch sensor 10 is touched by an object during a period of time when external power source 24 supplies power to device 8. Noise signal 30 may be sensed in any suitable manner. As an example and not by way of limitation, a portion of touch sensor 10 (such as a sense electrode or sense line) may be sampled. At step 62, a synchronization signal 42 is generated based on the sensed noise signal 30. In particular embodiments, synchronization signal 42 is synchronized to the noise signal 30. As an example and not by way of limitation, synchronization signal 42 may include a series of electrical pulses that are each generated when a particular portion of a repeating pattern of noise signal 30 is sensed. At step 64, a measurement signal 46 is generated based on the synchronization signal 42. In particular embodiments, the measurement signal 46 is synchronized to the noise signal 30. As an example and not by way of limitation, measurement signal 46 may include measurement events 48 comprising one or more drive pulses and each measurement event may be generated during a particular portion of a repeating pattern of noise signal 30. During step 64, measurement signal 46 may be adjusted to an optimum position with respect to the noise signal 30. As an example and not by way of limitation, the measurement events 48 of measurement signal 46 may be aligned with a particular portion of a repeating pattern of noise signal 30 such that the signal to noise ratio of a touch sensor measurement utilizing measurement signal 46 is maximized or above a predetermined value.

At step 66, a touch sensor measurement is performed. As an example and not by way of limitation, one or more measurement events 48 may be provided to a location of touch sensor 10, such as a drive electrode. Controller 12 may measure a response by the touch sensor 10 to the measurement events 48 and determine whether a touch has occurred at the location of the touch sensor 10. After step 66, the method may end. One or more steps may be repeated for subsequent touch sensor measurements. Particular embodiments may repeat the steps of the method of FIG. 4, where appropriate. Moreover, although this disclosure describes and illustrates particular steps of the method of FIG. 4 as occurring in a particular order, this disclosure contemplates any suitable steps of the method of FIG. 4 occurring in any suitable order. Furthermore, although this disclosure describes and illustrates particular components, devices, or systems carrying out particular steps of the method of FIG. 4, this disclosure contemplates any suitable combination of any suitable components, devices, or systems carrying out any suitable steps of the method of FIG. 4.

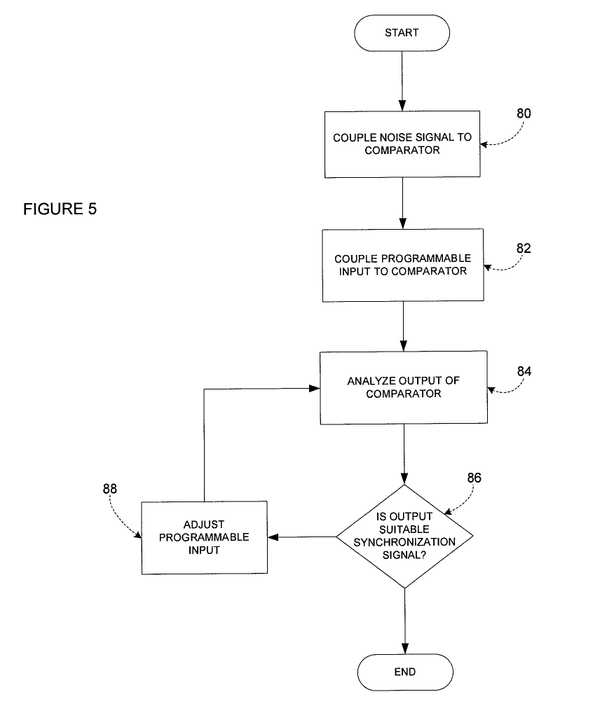

FIG. 5 illustrates an example method for generating a synchronization signal 42 that is synchronized to a noise signal 30. The method may begin at step 80, where noise signal 30 is coupled to a first input of a comparator. At step 82, a programmable input is coupled to a second input of the comparator. In particular embodiments, the programmable input may be a programmable voltage source capable of providing an adjustable voltage level to the comparator. The comparator may be operable to generate an active signal when the voltage level of noise signal 30 is higher than the voltage level provided by the programmable input. At step 84, the output of the comparator is analyzed to determine whether the output is a suitable synchronization signal 42. As an example and not by way of limitation, the output of the comparator may be analyzed to determine whether the output of the comparator produces signals that have a frequency that is substantially the same or related to a frequency of the noise signal 30. As another example, touch sensor measurements that utilize a measurement signal 46 based on the output of the comparator may be analyzed to determine whether a predetermined accuracy or signal-to-noise ratio is achieved. At step 86, if the output of the comparator is a suitable synchronization signal 42, the method ends. If the output of the comparator is not a suitable synchronization signal 42, the programmable input is adjusted at step 88. By way of example and not limitation, a voltage level provided by the programmable input may be lowered or raised. In particular embodiments, steps 84, 86, and 88 may be repeated until a suitable synchronization signal is obtained.

Particular embodiments may repeat the steps of the method of FIG. 5, where appropriate. Moreover, although this disclosure describes and illustrates particular steps of the method of FIG. 5 as occurring in a particular order, this disclosure contemplates any suitable steps of the method of FIG. 5 occurring in any suitable order. Furthermore, although this disclosure describes and illustrates particular components, devices, or systems carrying out particular steps of the method of FIG. 5, this disclosure contemplates any suitable combination of any suitable components, devices, or systems carrying out any suitable steps of the method of FIG. 5.

Particular embodiments may provide a touch sensor capable of measurement-to-noise synchronization. Such embodiments may enhance the measurement capabilities of a touch sensor. Particular embodiments may facilitate accurate touch sensor measurements while a device is coupled to an external power source that produces noise. Particular embodiments may provide for adjustment to various noise patterns.

Herein, reference to a computer-readable storage medium encompasses one or more non-transitory, tangible computer-readable storage media possessing structure. As an example and not by way of limitation, a computer-readable storage medium may include a semiconductor-based or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. Herein, reference to a computer-readable storage medium excludes any medium that is not eligible for patent protection under 35 U.S.C. §101. Herein, reference to a computer-readable storage medium excludes transitory forms of signal transmission (such as a propagating electrical or electromagnetic signal per se) to the extent that they are not eligible for patent protection under 35 U.S.C. §101. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

This disclosure encompasses all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A method comprising:
sensing by a touch sensor a periodic noise signal caused by an external power source removably coupled to the touch sensor;
generating a measurement signal that is synchronized to the periodic noise signal;
transmitting the measurement signal to a location of the touch sensor; and
detecting whether a touch has occurred at or near the location of the touch sensor based on a response of the location of the touch sensor to the measurement signal.

2. The method of claim 1, wherein:
the method further comprises generating a synchronization signal comprising a plurality of synchronization events that occur at a frequency that is substantially the same or related to the frequency of the noise signal; and
the measurement signal comprises a plurality of measurement events, each measurement event generated in response to a distinct synchronization event of the plurality of synchronization events.

3. The method of claim 2, wherein each synchronization event is an electrical pulse generated by a comparator coupled to the periodic noise signal and a programmable voltage source.

4. The method of claim 3, further comprising adjusting a voltage level of the programmable voltage source if an output of the comparator is not synchronized to the periodic noise signal.

5. The method of claim 2, further comprising adjusting a programmable delay between the synchronization signal and the measurement signal to substantially align the beginning of each measurement event with a particular portion of a generally repeating pattern of the periodic noise signal.

6. The method of claim 1, wherein the measurement signal comprises a plurality of electrical pulses.

7. The method of claim 1, wherein the periodic noise signal is a common mode noise signal coupled to the touch sensor during a touch of the touch sensor by an object.

8. An apparatus comprising:
a touch sensor operable to sense a periodic noise signal caused by an external power source removably coupled to the touch sensor; and
one or more computer-readable non-transitory storage media coupled to the touch sensor and embodying logic that is configured when executed to:
generate a measurement signal that is synchronized to the periodic noise signal;
transmit the measurement signal to a location of the touch sensor; and
detect whether a touch has occurred at or near the location of the touch sensor based on a response of the location of the touch sensor to the measurement signal.

9. The apparatus of claim 8, further comprising:
a synchronization signal generator operable to generate a synchronization signal comprising a plurality of synchronization events that occur at a frequency that is substantially the same or related to the frequency of the noise signal; and wherein:
the measurement signal comprises a plurality of measurement events, each measurement event generated in response to a distinct synchronization event of the plurality of synchronization events.

10. The apparatus of claim 9, wherein each synchronization event is an electrical pulse generated by a comparator coupled to the periodic noise signal and a programmable voltage source.

11. The apparatus of claim 10, wherein the synchronization signal generator is further operable to adjust a voltage level of the programmable voltage source if an output of the comparator is not synchronized to the periodic noise signal.

12. The apparatus of claim 9, wherein the logic is further operable to adjust a programmable delay between the synchronization signal and the measurement signal to substantially align the beginning of each measurement event with a particular portion of a generally repeating pattern of the periodic noise signal.

13. The apparatus of claim 8, wherein the measurement signal comprises a plurality of electrical pulses.

14. The apparatus of claim 8, wherein the periodic noise signal is a common mode noise signal coupled to the touch sensor during a touch of the touch sensor by an object.

15. An apparatus, comprising:
a capacitive touch sensor; and
a control unit coupled to the capacitive touch sensor, the control unit operable to:
sense a periodic noise signal caused by an external power source removably coupled to the capacitive touch sensor;
generate a measurement signal that is synchronized to the periodic noise signal;
transmit the measurement signal to a location of the capacitive touch sensor; and
detect whether a touch has occurred at or near the location of the capacitive touch sensor based on a response of the location of the capacitive touch sensor to the measurement signal.

16. The apparatus of claim 15, wherein:
the control unit is further operable to generate a synchronization signal comprising a plurality of synchronization events that occur at a frequency that is substantially the same or related to the frequency of the noise signal; and
the measurement signal comprises a plurality of measurement events, each measurement event generated in response to a distinct synchronization event of the plurality of synchronization events.

17. The apparatus of claim 16, wherein each synchronization event is an electrical pulse generated by a comparator coupled to the periodic noise signal and a programmable voltage source.

18. The apparatus of claim 17, the control unit is further operable to adjust a voltage level of the programmable voltage source if an output of the comparator is not synchronized to the periodic noise signal.

19. The apparatus of claim 16, the control unit is further operable to adjust a programmable delay between the synchronization signal and the measurement signal to substantially align the beginning of each measurement event with a particular portion of a generally repeating pattern of the periodic noise signal.

20. The apparatus of claim 15, wherein the measurement signal comprises a plurality of electrical pulses.
